(19) United States
(12) Patent Application Publication
(10) Pub. No.: US 2007/0011576 A1
(43) Pub. Date: Jan. 11, 2007

(54) DATA MANAGING METHOD AND OPTICAL DISC DRIVE FOR HANDLING AN DECODING ERROR OF A READBACK DATA RETRIEVED FROM AN OPTICAL DISC

(76) Inventors: Yuan-Ting Wu, Hsin-Chu City (TW); Shih-Hsin Chen, Tao-Yuan Hsien (TW); Ping-Sheng Chen, Chiayi County (TW)

Correspondence Address: NORTH AMERICA INTELLECTUAL PROPERTY CORPORATION, P.O. BOX 506, MERRIFIELD, VA, 22116, US

(21) Appl. No.: 11/308,120

(22) Filed: Mar. 7, 2006

(30) Foreign Application Priority Data
Jun. 7, 2005 (TW) 094118788

(51) Int. Cl. G11C 29/00

(52) U.S. Cl. 714/763

(57) ABSTRACT

A data managing method and optical disc drive capable of handling decoding errors of readback data retrieved from an optical disc. The data managing method includes providing a buffering pointer and a decoding pointer; utilizing the buffering pointer to indicate an address utilized for storing an un-decoded readback data; controlling the decoding pointer to indicate a starting address of a data block currently being decoded; and when a decoding error occurs during decoding a specific data sector in the data block, updating the buffering pointer to indicate that the address of the storage device utilized for storing the un-decoded readback data corresponds to the staring address indicated by the decoding pointer for re-retrieving an un-decoded readback data corresponding to the data block.

### BACKGROUND

The disclosure relates to a method of handling decoding errors and a related apparatus, and more particularly, to a data managing method and optical disc drive for handling decoding errors of readback data retrieved from an optical disc.

Typically, the conventional optical disc accessing method utilizes a data sector as a decoding unit. When a decoding error occurs and the un-decoded data must be re-retrieved from the optical disc, it is sufficient to re-retrieve only the data sector associated with the decoding error from the optical disc and then decode the data sector again. This conventional method is quite simple to practice utilizing either hardware or software. However, for the digital versatile disc (DVD), Blu-ray (BD) disc, or High-definition DVD (HD-DVD), the decoding unit of the data refers to a data block, which is composed of a plurality of data sectors, rather than a single data sector. Therefore, once a decoding error occurs during decoding of a data sector and the un-decoded data must be re-retrieved from the optical disc, the process becomes more difficult and complicated when compared with the data accessing method of the typical optical disc. As it is well known in the pertinent art, a data block of the digital versatile disc is composed of sixteen data sectors, wherein the data block is the so-called ECC block; a data block of the Blue-ray disc is composed of thirty-two data sectors, wherein the data block is the so-called cluster; and a data block of the High-definition DVD is composed of thirty-two data sectors, wherein the data block is the so-called data segment.

Please refer to FIG. 1. FIG. 1 is a block diagram of a conventional optical disc drive 100. The optical disc drive 100 can handle decoding errors of readback data retrieved from an optical disc 102. The optical disc drive 100 includes a storage device 110 (e.g., a dynamic random access memory), a control circuit 120, and a decoding circuit 130. The storage device 110 is regarded as a ring buffer for storing the readback data retrieved from the optical disc 102. As shown in FIG. 1, the storage space of the storage device 110 can be divided into a plurality of data blocks BK₁-BKₙ, wherein each data block includes a plurality of data sectors SC₁-SCₘ. In practice, for the digital versatile disc, the value of m is equal to 16 (i.e., each ECC block includes 16 sectors); and for the Blu-ray disc and the High-definition DVD, the value of m is equal to 32 (i.e., each cluster and each data segment includes 32 sectors). As one of ordinary skill in the art would understand, the data stored in the optical disc will be processed in advance via an interleaving operation. Therefore, a de-interleaving operation will be performed before storing data of an optical disc into the storage device 110. That is, data belonging to the same data sector are stored in the storage device 110 consecutively. Moreover, another conventional method of directly storing the data of an optical disc into the storage device 100 can be utilized. That is, the data stored in the storage device 110 have not yet been de-interleaved. In this way, the decoding circuit 130 must be capable of performing the desired de-interleaving function, that is, the decoding circuit 130 must include a de-interleaving circuit to ensure the subsequent decoding process is executed smoothly.

In addition, the value of n is determined by the storage capacity of the storage device 110. That is, as the storage capacity (i.e., space) increases so does the amount of data blocks that can be recorded into the storage device 110 (i.e., the value of n grows). The control circuit 120 is coupled to the storage device 110 and includes a buffering pointer BP, a decoding pointer DP, and a reading pointer RP for controlling the storing and retrieving of the readback data in the storage device 110. In other words, the control circuit 120 can control a pick-up head (not shown) to read the data from the optical disc 102, and store the readback data in the storage device 110. In addition, the control circuit 120 also can control the storage device 110 to send the inner readback data, which has been decoded, to the host 104. The decoding circuit 130, coupled to the control circuit 120 and the storage device 110, is for decoding the readback data stored in the storage device 110. Moreover, the decoding circuit 130 performs decoding process on each data sector acting as a basic decoding unit and the decoding process further includes the conventional error correction operation. If a decoding error occurs during the process of the decoding circuit 130 decoding a data sector, the decoding circuit 130 will output a signal S to inform the control circuit 120 to adjust the buffering pointer BP, the decoding pointer DP, and the reading pointer RP. The function and correlation of the readback data in the storage device 110 and all pointers BP, DP, and RP of the control circuit 120 is briefly described as follows.

Please refer to FIG. 2. FIG. 2 is a schematic diagram illustrating the buffering pointer BP, the decoding pointer DP, and the reading pointer RP shown in FIG. 1 indicating the corresponding addresses of the storage device 110. The readback data Data_1 includes an un-decoded readback data Data_2, a decoding readback data Data_3 (i.e., the specific data sector currently being decoded) and a decoded readback data Data_4. The buffering pointer BP is utilized to indicate a starting address utilized for storing an un-decoded readback data retrieved from the optical disc 102 into the storage device 110. That is, the un-decoded readback data is stored into the storage device 110 just after the un-decoded readback data Data_2 is stored into the storage device 110. The decoding pointer DP is utilized to indicate the starting address of the decoding readback data Data_3 on the storage device 110 (i.e., a starting address of a specific data sector). The reading pointer RP is utilized to indicate the address of the decoded readback data that is currently waiting to be read by the host 104 (e.g., a personal computer). In addition, under the normal operation (i.e., a decoding error does not occur), if the data reading speed of the host 104 is faster then the data decoding speed of the decoding circuit 130, it might be possible that the decoded readback data Data_4 has completely been read by the host 104 during the process of the decoding circuit 130 decoding the decoding readback Data_3. Thus, the readback data Data_1 only includes the un-decoded readback data Data_2 and the decoding readback data Data_3. At present, the reading pointer RP will remain at the ending address of the former data sector of the decoding readback data Data_3. When the decoding readback data Data_3 has been decoded successfully, the decoding pointer DP then moves to the starting address of the next data sector of the decoding readback data Data_3, and the reading pointer RP will indicate the starting address of the decoding readback data Data_3.

As well known in the pertinent art, the optical disc drive 100 will perform an operation of handling the decoding error of a readback data retrieved from the optical disc 102 under three situations. The first situation is: when a decoding error occurs, the starting address of the decoding readback data Data_3 (corresponding to a data sector), which is indicated by the decoding pointer DP, on the storage device 110 is just the starting position of the data block corresponding to the decoding readback data Data_3; the second situation is: when a decoding error occurs, the decoding pointer DP and the reading pointer RP do not indicate the same data block, and the starting address of the decoding readback data Data_3 (corresponding to a data sector), which is indicated by the decoding pointer DP, on the storage device 110 is not the starting position of the data block corresponding to the decoding readback data Data_3; and the third situation is: when a decoding error occurs, the decoding pointer DP and the reading pointer RP indicate the same data block, and the starting address of the decoding readback data Data_3 (corresponding to a data sector), which is indicated by the decoding pointer DP, on the storage device 110 is not the starting position of the data block corresponding to the decoding readback data Data_3.

Please refer to FIG. 1 and FIG. 3 simultaneously. FIG. 3 is a schematic diagram illustrating a first embodiment of the conventional data managing method applied in the optical disc drive 100 for handling the decoding error shown in FIG. 1. At time T₃, the buffering pointer BP indicates that the starting address utilized for storing the un-decoded readback data retrieved from the optical disc 102 into the storage device 110 is the starting address of the next data sector of the data sector SC_{y} (the value of y is less than or equal to the value of m). The decoding pointer DP indicates the starting address of the data sector SC₁ that is currently being decoded. (Please note that the data sector SC₁ is the first data sector of the data block BKᵢ₊₃). The reading pointer RP indicates the address of the decoded readback data that is currently waiting to be read by the host 104, namely the starting address of the data sector SCₓ (the value of x is less than or equal to the value of m). When the decoding circuit 130 is performing the decoding operation to the data sector SC₁ and a decoding error occurs, the decoding circuit 130 will output a signal S to inform the control circuit 120. The data sector SC₁ is the first data sector of the data block BKᵢ₊₃. Therefore, at time T₃′, the control circuit 120 only needs to update the buffering pointer BP for indicating the starting address of the data sector SC₁. According to the updated buffering pointer BP, the optical disc drive 100 will restore the un-decoded readback data corresponding to the data block BKᵢ₊₃ (e.g., from the data sector SC₁ to the data sector SC_{y}) retrieved from the optical disc 102 into the storage device 110. As mentioned above, in this first situation, the optical disc drive 100 needs to adjust one pointer (i.e., the buffering pointer BP).

Please refer to FIG. 1 and FIG. 4 simultaneously. FIG. 4 is a schematic diagram illustrating a second embodiment of the conventional data managing method applied in the optical disc drive 100 for handling the decoding error shown in FIG. 1. At time T₄, the buffering pointer BP indicates that the starting address utilized for storing the un-decoded readback data retrieved from the optical disc 102 into the storage device 110 is the starting address of the next data sector of the data sector SC_{y} (the value of y is less than or equal to the value of m). The decoding pointer DP indicates the starting address of the data sector SC_{z} (the value of z is less than or equal to the value of m) that is currently being decoded. Please note that the data sector SC_{z} is not the first data sector of the data block BKᵢ₊₃. The reading pointer RP indicates the address of the decoded readback data that is waiting to be read by the host 104, namely the starting address of the data sector SCₓ (the value of x is less than or equal to the value of m). When the decoding circuit 130 proceeds to decode the data sector SC_{z} and a decoding error occurs, the decoding circuit 130 will output a signal S to inform the control circuit 120. The data sector SC_{z} is not the first data sector of the data block BKᵢ₊₃. Therefore, at time T₄′, the control circuit 120 needs to update both the buffering pointer BP and the decoding pointer DP to indicate the starting address of the data block BKᵢ₊₃. According to the updated buffering pointer BP, the optical disc drive 100 will restore the un-decoded readback data corresponding to the data block BKᵢ₊₃ retrieved from the optical disc 102 into the storage device 110. In addition, the optical disc drive 100 will continue the decoding operation with the following data sector after the data block BKᵢ₊₃ according to the updated decoding pointer DP. As mentioned above, in this second situation, the optical disc drive 100 must adjust two pointers (i.e., the buffering pointer BP and the decoding pointer DP).

Please refer to FIG. 1 and FIG. 5 simultaneously. FIG. 5 is a schematic diagram illustrating a third embodiment of the conventional data managing method applied in the optical disc drive 100 for handling the decoding error shown in FIG. 1. At time T₅, the buffering pointer BP indicates that the starting address utilized for storing the un-decoded readback data retrieved from the optical disc 102 into the storage device 110 is the starting address of the next data sector of the data sector SC_{y} (the value of y is less than or equal to the value of m). The decoding pointer DP indicates the starting address of the data sector SC_{z} (the value of z is less than or equal to the value of m) which currently being decoded. Please note that the data sector SC_{z} is not the first data sector of the data block BKᵢ₊₃. The reading pointer RP indicates the address of the decoded readback data that is waiting to be read by the host 104, namely the starting address of the data sector SCⱼ (the value of j is less than or equal to the value of m). As shown is FIG. 5, the data sector SCⱼ and the data sector SC_{z} are both located in the same data block BKᵢ₊₃. When the decoding circuit 130 continues the decoding operation to the data sector SC_{z} and a decoding error occurs, the decoding circuit 130 will output a signal S to inform the control circuit 120, Therefore, at time T₅′, the control circuit 120 must update both the buffering pointer BP and the decoding pointer DP (the address which the reading pointer RP indicates is not changed) to indicate the starting address of the data block BKᵢ₊₃. According to the updated buffering pointer BP, the optical disc drive 100 will restore the un-decoded readback data corresponding to the data block BKᵢ₊₃ retrieved from the optical disc 102 into the storage device 110, and also perform the decoding operation again with the following data sector after the data block BKᵢ₊₃ according to the updated decoding pointer DP. In addition, since the address corresponding to the reading pointer RP overtakes the address corresponding to the decoding pointer DP the optical disc drive 100 will suspend from sending the decoded readback data stored in the storage device 110 to the host 104 until the address corresponding to the decoding pointer DP overtakes the address corresponding to the reading pointer RP. As mentioned above, in this third situation, the optical disc drive 100 needs to adjust two pointers (i.e., the buffering pointer BP and the decoding pointer DP), and also must remember the data, which has been read by the host, to avoid the situation wherein the data is read more than once by the host.

As shown from FIG. 3 to FIG. 5, when a decoding error occurs during decoding a data sector in the data block BKᵢ₊₃ (i.e., the above-mentioned first, second, and third situations), the data block BKᵢ₊₃ will be reprocessed with the decoding operation. If the data block BKᵢ₊₃ cannot be decoded successfully after a plurality of trials, the conventional optical disc drive 100 will abandon the decoding operation of the un-decoded data sector in the data block BKᵢ₊₃. When the host 104 requests the data information about the data block BKᵢ₊₃, the conventional optical disc drive 100 will send the information of the data sector which has been decoded in the data block BKᵢ₊₃ to the host 104. If the host 104 requests to send the information of the un-decoded data sector in the data block BKᵢ₊₃, the conventional optical disc drive 100 will reply to the to the host 104 with a decoding error message.

In conclusion, since the decoding pointer DP does not immutably indicate a starting address or ending address of a data block, but randomly indicates any data sector of the data lock. As a result, once a decoding error occurs, the conventional data managing method of handling a decoding error by needing to process appropriate adjustments to the buffering pointer BP and the decoding pointer DP according to different situations is initiated. However, since the determining mechanism is so complicated it will increase the complexity of the entire optical disc drive 100. Moreover, the performance of the optical disc drive 100 to handle a decoding error will be affected resulting in a decrease in performance.

### SUMMARY OF THE INVENTION

It is therefore one of the objectives of the claimed disclosure to provide a data managing method and optical disc drive for handling a decoding error of a readback data retrieved from an optical disc, to solve the above-mentioned problem.

According to an aspect of the present disclosure, a data managing method of handling decoding errors of a readback data retrieved from an optical disc is disclosed. The readback data is stored in a storage device of an optical disc drive, and the readback data comprises a plurality of data blocks and each of the data blocks comprises a plurality of data sectors. The data managing method comprises: (a) providing a buffering pointer and a decoding pointer; (b) utilizing the buffering pointer to indicate an address used for storing an un-decoded readback data retrieved from the optical into the storage device; (c) utilizing the decoding pointer to indicate a starting address of a data block currently being decoded in the readback data, wherein before all of the data sectors in the data block have been decoded successfully, the decoding pointer continually indicates the starting address of the data block; and (d) when a decoding error occurs during decoding a specific data sector in the data block, updating the buffering pointer to indicate that the address of the storage device used for storing the un-decoded readback data corresponds to the address indicated by the decoding pointer for re-retrieving an un-decoded readback data corresponding to the data block from the optical disc.

According to another aspect of the present disclosure, an optical disc drive capable of handling decoding errors of a readback data retrieved from an optical disc is disclosed. The optical disc drive comprises a storage device, a control circuit, and a decoding circuit. The storage device is used for storing the readback data, wherein the readback data comprises a plurality of data blocks, and each of the data blocks comprises a plurality of data sectors. The control circuit, coupled to the storage device, is used for controlling data accessing of the storage device, and the control circuit comprises: a buffering pointer for indicating an address used for storing an un-decoded readback data retrieved from the optical disc into the storage device; and a decoding pointer for indicating a starting address of a data block currently being decoded in the readback data, wherein before all of the data sectors in the data block have been decoded successfully, the decoding pointer continually indicates the starting address of the data block. The decoding circuit is coupled to the control circuit and the storage device. When a decoding error occurs during decoding a specific data sector in the data block, the control circuit updates the buffering pointer to indicate that the address of the storage device used for storing the un-decoded readback data corresponds to the address indicated by the decoding pointer for re-retrieving an un-decoded readback data corresponding to the data block from the optical disc.

The data managing method in the present disclosure and the optical disc drive applied by the data managing method further provide a additional decoding pointer to replace the function of the conventional decoding pointer. The decoding pointer disclosed in the present disclosure will continually indicate the starting address of the decoding data block without change before all data sectors of the decoding data block have been successfully decoded. Therefore, it is not necessary for the present disclosure to perform different process for different situation as the conventional skill when a decoding error occurs. In conclusion, the data managing method in the present disclosure and the optical disc drive applied by the data managing method can reduce the complex of the whole system significantly and the performance of the optical disc drive for handling a deciding error is also improved substantially.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a block diagram of a conventional optical disc drive.

FIG. 2 is a schematic diagram illustrating the buffering pointer BP, the decoding pointer DP, and the reading pointer RP shown in FIG. 1.

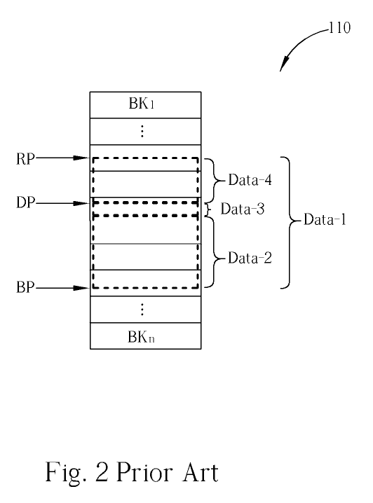

FIG. 3 is a schematic diagram illustrating a first embodiment of the conventional data managing method applied in the optical disc drive for handling the decoding error shown in FIG. 1.

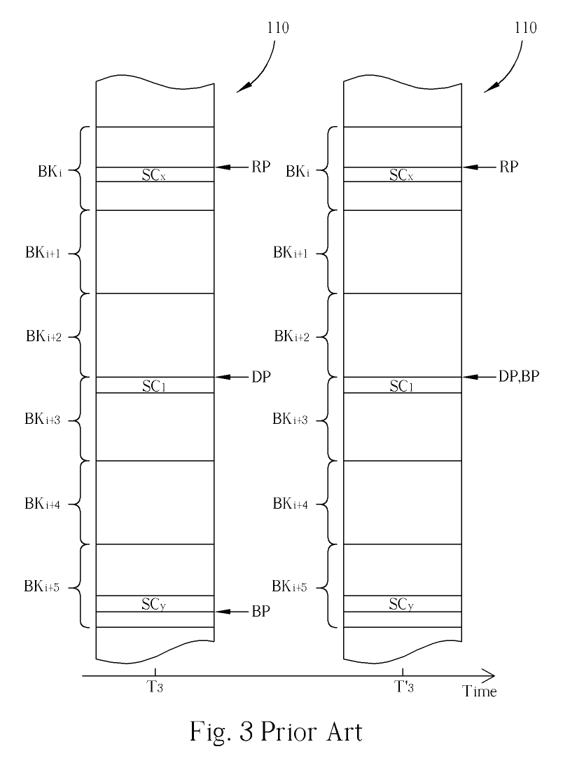

FIG. 4 is a schematic diagram illustrating a second embodiment of the conventional data managing method applied in the optical disc drive for handling the decoding error shown in FIG. 1.

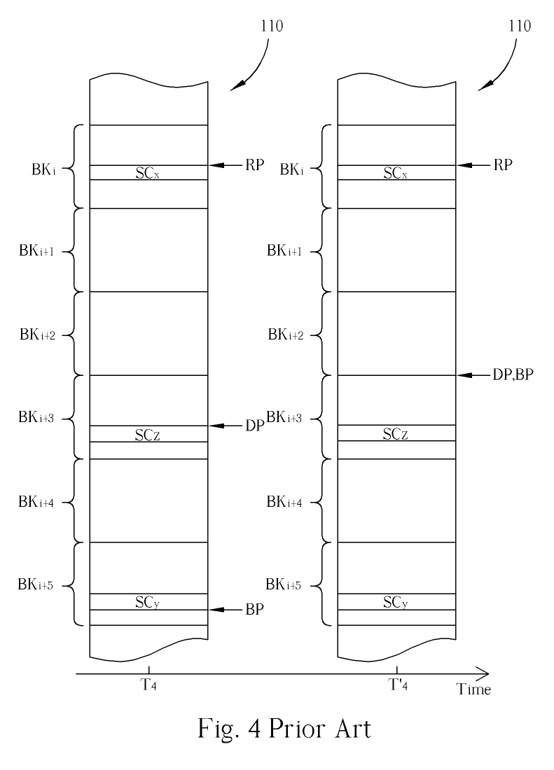

FIG. 5 is a schematic diagram illustrating a third embodiment of the conventional data managing method applied in the optical disc drive for handling the decoding error shown in FIG. 1.

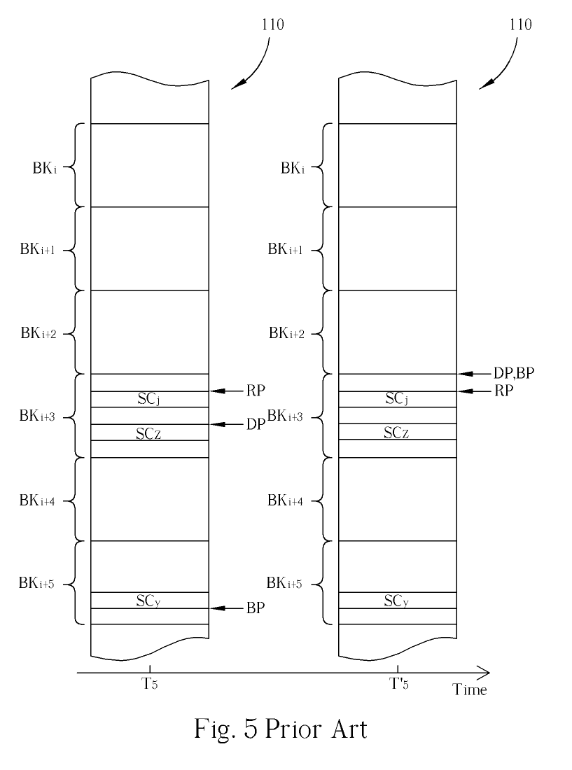

FIG. 6 is a block diagram of an optical disc drive according to a first embodiment of the present disclosure.

FIG. 7 is a schematic diagram illustrating a first embodiment of the data managing method in the present disclosure applied in the optical disc drive shown in FIG. 6 for handling the decoding error.

### DETAILED DESCRIPTION

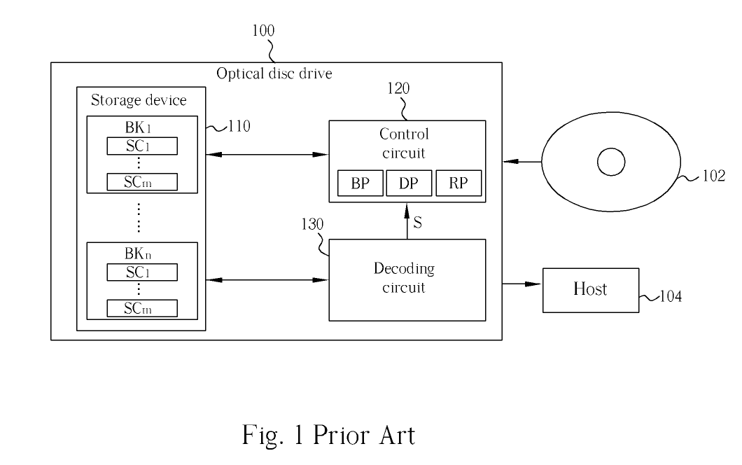

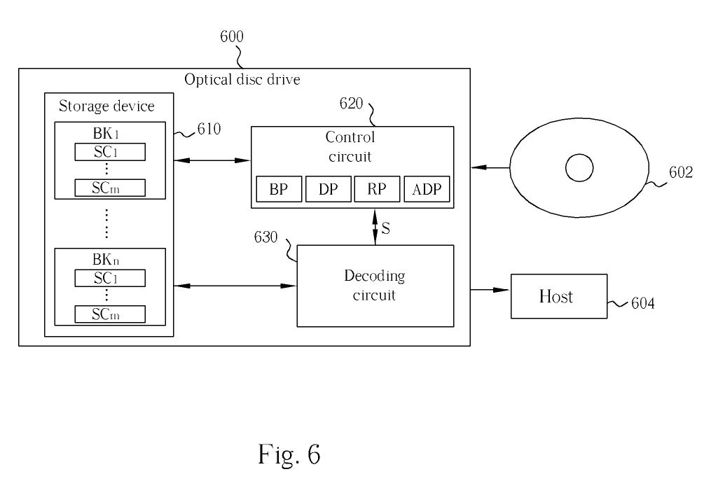

Please refer to FIG. 6. FIG. 6 is a block diagram of an optical disc drive 600 according to a first embodiment of the present disclosure. The function and operation of the optical disc drive 600 is similar to the optical disc drive 100 shown in FIG. 1, which means that the optical disc drive 600 can also handle a decoding error of a readback data retrieved from an optical disc 602 (e.g., a DVD). In this preferred embodiment, the optical disc drive 600 includes a storage device 610 (e.g., dynamic random access memory), a control circuit 620, and a decoding circuit 630. In this embodiment, the storage device 610 is functions as a ring buffer for storing the readback data retrieved from the optical disc 602. However, please note that the ring buffer is only an embodiment of the storage device 610. In the present disclosure, the storage device 610 is not limited in the framework of the ring buffer. As shown in FIG. 6, the storage space of the storage device 610 can be perceived as dividing into a plurality of data block BK₁-BKₙ, wherein each data block includes a plurality of data sector SC₁-SCₘ. For the digital versatile disc, the value of m is equal to 16 (i.e., each ECC block includes 16 sectors), and for the Blu-ray disc and the High-definition DVD, the value of m is equal to 32 (i.e., each cluster and each data segment includes 32 sectors).

In addition, the value of n is determined by the storage space of the storage device 610; therefore, the more the storage space is, the more the amount of the data block can be recorded in the storage device 610 (i.e., the more value of n). The main different between the optical disc drive 600 of the present disclosure and the conventional optical disc drive 100 is that the control circuit 620 not only includes the conventional buffering pointer BP, the decoding pointer DP and the reading pointer RP, but also further sets an actual decoding pointer DP. Moreover, the control circuit 620 also provides a new control mechanism for controlling the decoding pointer DP, and the related operation is detailed latter. The decoding circuit 630 couples to the control circuit 620 and the storage device 610 for decoding the readback data stored in the storage device 610. Furthermore, if a decoding error occurs during decoding a data sector, the decoding circuit 630 will output a signal S to inform the control circuit 620, and the control circuit 620 will further determine how to adjust the buffering pointer BP, the actual decoding pointer ADP, and the reading pointer RP.

Since the function and operation of the buffering pointer BP and the reading pointer RP is same as the conventional well-known skill, detailed description is omitted for the sake of brevity. For the decoding pointer DP, the control circuit 620 controls the decoding pointer DP to indicate the starting address of a data block that is currently being decoded. Please note that, one of the differences between the present disclosure and the conventional skill is that the decoding pointer DP will continually indicate a starting address of the decoding data block without change before all data sectors (SC₁-SCₘ) of the data block have been successfully decoded. In addition, the control circuit 620 further utilizes the actual decoding pointer ADP to indicate a starting address of the data sector that is being decoded in the decoding data block, and the function of the actual decoding pointer ADP is same as the conventional decoding pointer DP. In other words, since the operation of the decoding pointer DP of this embodiment is different with the original operation of the decoding pointer DP in the conventional skill, the new added actual decoding pointer ADP is utilized for replacing the function of the original decoding pointer DP. Please note that, as well known in the pertinent art, under the normal operation (a decoding error does not occur) the movements of the address corresponding to the decoding pointer DP and the movements of the address corresponding to the reading pointer RP will not surpass the address corresponding to the buffering point BP, and the movements of the address corresponding to the reading pointer RP will not surpass the address corresponding to the decoding pointer DP.

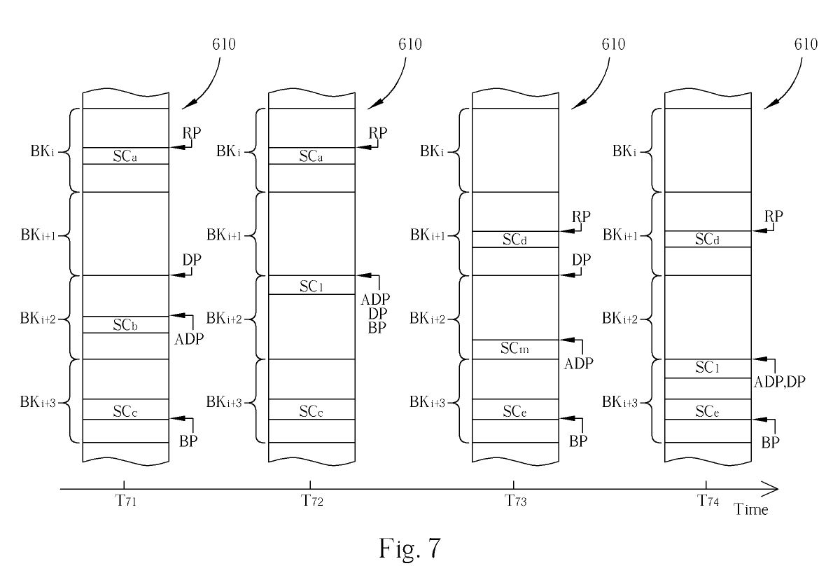

Please refer to FIG. 6 and FIG. 7 simultaneously. FIG. 7 is a schematic diagram illustrating a first embodiment of the data managing method in the present disclosure applied in the optical disc drive 600 shown in FIG. 6 for handling the decoding error. At time T₇₁, the buffering pointer BP indicates that the starting address utilized for storing the un-decoded readback data retrieved from the optical disc 602 into the storage device 610 is the starting address of the next data sector of the data sector SC_{c} (the value of c is less than or equal to the value of m). The decoding pointer DP indicates the starting address of the data block BKᵢ₊₂ that is currently being decoded. The actual decoding pointer ADP indicates the starting address of the data sector SC_{b} (the value of b is less than or equal to the value of m) that is currently being decoded. The reading pointer RP indicates the address of the decoded readback data that is waiting to be read by the host 604, namely the starting address of the data sector SCₐ (the value of a is less than or equal to the value of m). When the decoding circuit 630 proceeds with the decoding operation to the data sector SC_{b} and a decoding error occurs, the decoding circuit 630 will output a signal S to inform the control circuit 620. Therefore, at time T₇₂, the control circuit 620 only needs to update the buffering pointer BP and the actual decoding pointer ADP for both indicating the starting address of the data block BKᵢ₊₂. According to the updated buffering pointer BP, the optical disc drive 600 will restore the un-decoded readback data corresponding to the data block BKᵢ₊₂ retrieved from the optical disc 602 into the storage device 610. And the optical disc drive 600 also re-processes the decoding operation from the first data sector SC₁ in the data block BKᵢ₊₂ according to the updated actual decoding pointer ADP. Since not all data sectors in the data block BKᵢ₊₂ have been successfully decoded, the decoding pointer DP will continually indicate the starting address of the data block BKᵢ₊₂.

At time T₇₃, the buffering pointer BP indicates that the starting address utilized for storing the un-decoded readback data retrieved from the optical disc 602 into the storage device 610 is the starting address of the next data sector of the data sector SCₑ (the value of e is less than or equal to the value of m). The decoding pointer DP continuously indicates the starting address of the data block BKᵢ₊₂. The actual decoding pointer ADP indicates the starting address of the data block SCₘ that is currently being decoded (i.e., the data block SCₘ is the last data sector of the data block BKᵢ₊₂). The reading pointer RP indicates the address of the decoded readback data that is waiting to be read by the host 604, namely the starting address of the data sector SC_{d} (the value of d is less than or equal to the value of m). When the decoding circuit 630 successfully processes the decoding operation to the data sector SCₘ, it means all data sectors in the data block BKᵢ₊₂ have been successfully decoded. Therefore, at time T₇₄, the control circuit 620 will update both the buffering pointer BP and the actual decoding pointer ADP to both indicate the starting address of the data block BKᵢ₊₃. Thus, according to the updated actual buffering pointer ABP, the optical disc drive 600 starts to process the decoding operation from the first data sector SC₁ in the data block BKᵢ₊₃. As mentioned above, for the optical disc drive 600, when a decoding error occurs, the optical disc drive 600 only needs to adjust two pointers (i.e. the buffering pointer BP and the actual decoding pointer ADP).

In this embodiment, if the decoding operation of a certain decoding data block cannot be successfully finished, the control circuit 620 can appropriately adjust the reading pointer RP, the actual decoding point, and the decoding pointer DP for directly abandoning all of the information of the data block without sending them to the host 604. That is, even if some data sectors of the data block have been decoded, the decoded readback data corresponding to the decoded data sectors will still been abandoned. Additionally, if a certain decoding data block can not successfully finishes the decoding operation, according to the actual decoding point and the decoding pointer DP, the control circuit 620 can also send the decoded readback data of the partly data sector have been successfully decoded of the data block to the host 604.

In contrast to the related art, the data managing method in the present disclosure and the optical disc drive applied by the data managing method further provide a additional decoding pointer to replace the function of the conventional decoding pointer. The decoding pointer disclosed in the present disclosure will continually indicate the starting address of the decoding data block without change before all data sectors of the decoding data block have been successfully decoded. Therefore, it is not necessary for the present disclosure to perform a different process for different situation as the conventional skill when a decoding error occurs. In conclusion, the data managing method in the present disclosure and the optical disc drive applied by the data managing method can reduce the complex of the whole system significantly and the performance of the optical disc drive for handling a deciding error is also improved substantially.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A data managing method of handling decoding errors of a readback data retrieved from an optical disc, the readback data being stored in a storage device of an optical disc drive, the readback data comprising a plurality of data blocks and each of the data block comprising a plurality of data sectors, the data managing method comprising:
(a) providing a buffering pointer and a decoding pointer;
(b) utilizing the buffering pointer to indicate an address utilized for storing an un-decoded readback data retrieved from the optical disc into the storage device;
(c) utilizing the decoding pointer to indicate a starting address of a data block currently being decoded in the readback data, wherein before all of the data sectors in the data block have been decoded successfully, the decoding pointer continually indicates the starting address of the data block; and
(d) when a decoding error occurs during decoding a specific data sector in the data block, updating the buffering pointer to indicate that the address of the storage device utilized for storing the un-decoded readback data corresponds to the address indicated by the decoding pointer for re-retrieving an un-decoded readback data corresponding to the data block from the optical disc.

2. The method of claim 1, further comprising:
(e) when step (d) has been performed repeatedly for a predetermined number of times, only sending the data which has been decoded successfully in the data block to a host.

3. The method of claim 2, wherein step (a) further comprises providing an actual decoding point, the method further comprises utilizing the actual decoding point to indicate a starting address of a data sector currently being decoded in the data block, and step (e) further comprises sending the data which has been decoded successfully to the host according to the decoding pointer and the actual decoding pointer.

4. The method of claim 1, wherein the storage device is a dynamic random access memory (DRAM).

5. The method of claim 1, wherein the optical disc is a digital versatile disc (DVD), a High-definition DVD (HD-DVD), or a Blu-ray disc (BD).

6. An optical disc drive capable of handling decoding errors of a readback data retrieved from an optical disc, the optical disc drive comprising:
a storage device for storing the readback data, wherein the readback data comprises a plurality of data blocks and each of the data blocks comprises a plurality of data sectors;
a control circuit, coupled to the storage device, for controlling data accessing of the storage device, the control circuit comprising:
a buffering pointer for indicating an address utilized for storing an un-decoded readback data retrieved from the optical disc into the storage device; and
a decoding pointer for indicating a starting address of a data block currently being decoded in the readback data, wherein before all of the data sectors in the data block have been decoded successfully, the decoding pointer continually indicates the starting address of the data block; and
a decoding circuit, coupled to the control circuit and the storage device;
wherein when a decoding error occurs during the decoding circuit decodes a specific data sector in the data block, the control circuit updates the buffering pointer to indicate that the address of the storage device utilized for storing the un-decoded readback data corresponds to the address indicated by the decoding pointer for re-retrieving an un-decoded readback data corresponding to the data block from the optical disc.

7. The optical disc drive of claim 6, wherein when the control circuit has been updated by the buffering pointer repeatedly for a predetermined number of times, the control circuit only sends the data which has been decoded successfully in the data block to a host.

8. The optical disc drive of claim 7, wherein the control circuit further comprises an actual decoding point for indicating a starting address of a data sector currently being decoded in the data block, and the control circuit sends the data which has been decoded successfully to the host according to the decoding pointer and the actual decoding pointer.

9. The optical disc drive of claim 6, wherein the storage device is a dynamic random access memory (DRAM).

10. The optical disc drive of claim 6, wherein the optical disc is a digital versatile disc (DVD), a High-definition DVD (HD-DVD), or a Blu-ray disc (BD).
